(19) United States
(12) Patent Application Publication
(10) Pub. No.: US 2011/0186927 A1
(43) Pub. Date: Aug. 4, 2011

(54) POWER SEMICONDUCTOR DEVICE

(75) Inventors: Yusuke KAWAGUCHI, Kanagawa-ken (JP); Takahiro Kawano, Kanagawa-ken (JP)

(73) Assignee: Kabushiki Kaisha Toshiba, Tokyo (JP)

(21) Appl. No.: 13/014,436

(22) Filed: Jan. 26, 2011

(30) Foreign Application Priority Data
Jan. 29, 2010 (JP) 2010-019692

(51) Int. Cl. H01L 29/78

(52) U.S. Cl. 257/342; 257/E29.256

(57) ABSTRACT

According to one embodiment, a power semiconductor device includes a first insulating film and a second insulating film. The first insulating film has a first dielectric constant and is formed on a bottom surface and a side surface of a trench formed by a second semiconductor layer. The trench is in contact with a fourth semiconductor layer and extends from a surface of the fourth semiconductor layer through a third semiconductor layer to the second semiconductor layer. The second insulating film is formed on a side surface of the trench formed by the third semiconductor layer and a side surface of the trench formed by the fourth semiconductor layer, being connected to the first insulating film. The second insulating film has a second dielectric constant higher than the first dielectric constant. The gate electrode is buried in the trench via the first and second insulating films.

### CROSS-REFERENCE TO RELATED APPLICATIONS

This application is based upon and claims the benefit of priority from the prior Japanese Patent Application No. 2010-019692, filed on Jan. 29, 2010; the entire contents of which are incorporated herein by reference.

### FIELD

Embodiments described herein relate generally to a power semiconductor device.

### BACKGROUND

Power supply circuits of portable communication devices such as notebook personal computers and cellular phones include MOSFETs (Metal Oxide Silicon Field Effect Transistors) as switching elements. To enable direct driving by a lithium ion battery, it is desired that the MOSFET have lower driving voltage and lower resistance. Furthermore, to reduce switching loss, reduction of gate-drain capacitance is desired.

The on-resistance of the MOSFET primarily depends on the channel resistance of the inversion layer (channel layer) formed from the inverted distribution between the base layer and the gate insulating film, and on the drift resistance of the drift layer. Conventionally, the trench gate structure suitable for miniaturization has been used to miniaturize the MOSFET. Consequently, the density of the channel layer has been increased to achieve lower on-resistance. However, it is difficult to further reduce the resistance. It is indeed possible to further reduce the channel resistance by thinning the gate insulating film formed on the trench sidewall to increase the carrier density in the channel layer formed at the interface between the base layer and the gate insulating film. However, due to thinning of the gate insulating film at the trench bottom, the voltage applied to the gate insulating film decreases and results in increasing the voltage applied to the interface between the gate insulating film and the drift layer. Increasing the impurity concentration of the drift layer to reduce the drift resistance hinders the depletion layer from extending at the interface between the gate insulating film and the drift layer. This results in decreasing the breakdown voltage at the trench bottom. Conventionally, to solve this problem, the gate insulating film opposed to the drift layer at the trench bottom is made thicker than the gate insulating film opposed to the base layer and the source layer. Thickening the gate insulating film at the trench bottom leads to, at the trench bottom, increasing the voltage applied to the gate insulating film and decreasing the voltage applied to the junction of the gate insulating film and the drift layer. Consequently, while maintaining the breakdown voltage of the interface between the drift layer and the gate insulating film at the trench bottom, the carrier density of the inversion layer formed at the interface between the base layer and the gate insulating film is increased to achieve lower channel resistance.

To reduce the gate-drain capacitance, a buried electrode electrically connected to the source electrode is formed opposite to the drift layer in the lower portion of the trench. Furthermore, above this buried electrode via an insulating film, a gate electrode opposed to the base layer and the source layer is formed in the upper portion of the trench.

Conventional techniques for further reducing the resistance by thickening the gate insulating film at the trench bottom have limitations because the trench bottom is filled with the gate insulating film. There is demand for a power semiconductor device capable of further reducing the on-resistance while maintaining high breakdown voltage.

### BRIEF DESCRIPTION OF THE DRAWINGS

FIG. 1 is a cross-sectional view of the principal part of a power semiconductor device of a first embodiment of the invention;

FIG. 2 is a cross-sectional view of the principal part of a power semiconductor device of a second embodiment of the invention;

FIG. 3 is a cross-sectional view of the principal part of a power semiconductor device of a third embodiment of the invention; and

FIG. 4 is a cross-sectional view of the principal part of a power semiconductor device of a fourth embodiment of the invention;

### DETAILED DESCRIPTION

In general, according to one embodiment, a power semiconductor device includes a first semiconductor layer of a first conductivity type, a second semiconductor layer of the first conductivity type, a third semiconductor layer of a second conductivity type, a fourth semiconductor layer of the first conductivity type, a first insulating film, a second insulating film, a gate electrode, an interlayer insulating film, a first main electrode, and a second main electrode. The second semiconductor layer of the first conductivity type is formed on a first major surface of the first semiconductor layer and has a lower impurity concentration than the first semiconductor layer. The third semiconductor layer of the second conductivity type is selectively formed in a surface of the second semiconductor layer. The fourth semiconductor layer of the first conductivity type is selectively formed in a surface of the third semiconductor layer. The first insulating film has a first dielectric constant and formed on a bottom surface and a side surface of a trench formed by the second semiconductor layer. The trench is in contact with the fourth semiconductor layer and extends from a surface of the fourth semiconductor layer through the third semiconductor layer to the second semiconductor layer. The second insulating film is formed on a side surface of the trench formed by the third semiconductor layer and a side surface of the trench formed by the fourth semiconductor layer. The second insulating film is connected to the first insulating film on the side surface of the trench formed by the second semiconductor layer. The second insulating film has a second dielectric constant higher than the first dielectric constant. The gate electrode is buried in the trench via the first insulating film and the second insulating film. The interlayer insulating film is formed on the gate electrode. The first main electrode is electrically connected to a second major surface of the first semiconductor layer on a side opposite to the first major surface. The second main electrode is formed on the surface of the fourth semiconductor layer and on the interlayer insulating film, is electrically connected to the third semiconductor layer and the fourth semiconductor layer, and is insulated from the gate electrode by the interlayer insulating film.

Embodiments of the invention will now be described with reference to the drawings. Although the embodiments are described assuming that the first conductivity type is n-type and the second conductivity type is p-type, the embodiments can also be practiced with these types interchanged. In the case where n-type impurity layers are labeled with symbols n⁻, n, and n⁺, it is assumed that the n-type impurity concentration in those layers increases in the order of n⁻<n<n⁺. This also applies to p-type impurity layers. Furthermore, unless otherwise specified, the impurity concentration refers to the net impurity concentration after compensation between the conductivity types.

The figures used in describing the embodiments are schematic for ease of description, and the shape, dimension, and size relation of components in the figures are not necessarily identical to those shown in the figures when they are actually put into practice. Furthermore, the shape, dimension, size relation, impurity concentration, and material can be modified as long as the effect of the invention is achieved.

Furthermore, unless otherwise specified, by way of example, the semiconductor layer refers to a semiconductor layer made of Si (silicon). However, other semiconductor layers, such as those made of SIC (silicon carbide) and AlGaN (aluminum gallium nitride), can also be used.

### First Embodiment

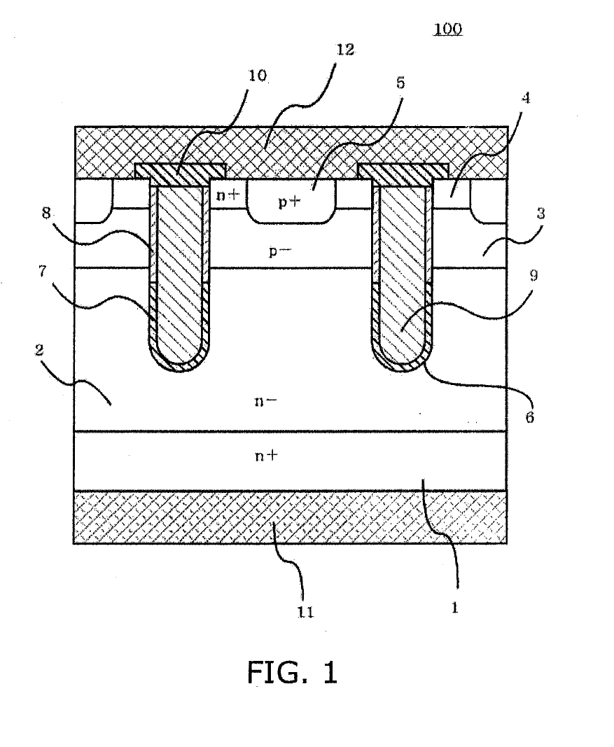

FIG. 1 is a diagram showing a cross section of the principal part of a current-flowing device region of a power semiconductor device according to a first embodiment of the invention. As shown in FIG. 1, the power semiconductor device 100 of the first embodiment of the invention is configured as follows.

On the first major surface of an n⁺-type semiconductor substrate 1 (a first semiconductor layer of the first conductivity type) made of silicon having a high n-type impurity concentration, an n⁻-type drift layer 2 (a second semiconductor layer of the first conductivity type) made of silicon having a lower n-type impurity concentration than the n⁺-type semiconductor substrate 1 is formed. A p⁻-type base layer 3 (a third semiconductor layer of the second conductivity type) made of silicon and having a p-type impurity concentration is formed selectively in the surface of the n⁻-type drift layer 2. An n⁺-type source layer 4 (a fourth semiconductor layer of the first conductivity type) made of silicon having a higher n-type impurity concentration than the n⁻-type drift layer 2 is formed selectively in the surface of the p⁻-type base layer 3. A p⁺-type contact layer 5 (a fifth semiconductor layer of the second conductivity type) made of silicon having a higher p-type impurity concentration than the p⁻-type base layer 3 is formed in the region sandwiched between the n⁺-type source layers 4 in the surface of the p⁻-type base layer 3. The p⁺-type contact layer 5 is formed in order to reduce the contact resistance between the source electrode described later and the p⁻-type base layer 3. However, the effect of the invention is sufficiently achieved even without the p⁺-type contact layer 5. The above layer structure can be formed on the n⁺-type semiconductor substrate 1 by successive epitaxial growth and impurity diffusion based on ion implantation. Alternatively, the above structure can be formed also by using an n⁻-type semiconductor substrate. In this case, on the first major surface of the n⁻-type semiconductor substrate, a p⁻-type semiconductor layer is formed by epitaxial growth or impurity diffusion based on ion implantation. Furthermore, on the second major surface on the opposite side from the first major surface of the n⁻-type semiconductor substrate, an n⁺-type semiconductor layer is formed similarly by epitaxial growth or impurity diffusion based on ion implantation. Thus, the aforementioned structure can be formed. On the upper surface of the n⁺-type semiconductor substrate 1, a drain electrode 11 as a first main electrode is formed and electrically connected to the n⁺-type substrate 1.

A trench 6 is formed in contact with the n⁺-type source layer 4 and extends from the surface of the n⁺-type source layer 4 through the p⁻-type base layer 3 to the n⁻-type drift layer 2. In the lower region of this trench 6 including its bottom surface, the bottom surface and side surface of the trench are formed by the n⁻-type drift layer 2. In the upper region of the trench 6, the side surface of the trench is mostly formed by the p⁻-type base layer 3. In the uppermost opening portion of the upper region of the trench 6, the side surface of the trench 6 is formed by the n⁺-type source layer 4.

On the bottom surface and side surface of the trench 6 thus formed by the n⁻-type drift layer 2, a first insulating film 7 having a first dielectric constant is formed. The upper end of the first insulating film is formed on the drain electrode 11 side (lower side) of the junction interface between the n⁻-type drift layer 2 and the p⁻-type base layer 3. The first insulating film is entirely buried in the n⁻-type drift layer 2. A second insulating film 8 is formed so as to extend on the region from the side surface of the uppermost portion of the trench 6 formed by the n⁺-type source layer 4 across the side surface formed by the p⁻-type base layer 3 to the side surface formed by the n⁻-type drift layer 2. The second insulating film 8 has a second dielectric constant higher than the first dielectric constant. In this embodiment, by way of example, the thickness of the second insulating film is set equal to the thickness of the first insulating film. As described later, the thickness of the first insulating film can be suitably selected depending on the impurity concentration of the n⁻-type drift layer 2. The second insulating film 8 is connected to the first insulating film 7 at a position near the p⁻-type base layer 3 on the side surface of the trench 6 formed by the n⁻-type drift layer 2. The first insulating film 7 and the second insulating film 8 cover entirely the bottom surface and side surface of the inside of the trench 6. That is, by the junction of the first insulating film 7 and the second insulating film 8 in the region near the p⁻-type base layer 3 on the side surface of the trench 6 formed by the n⁻-type drift layer 2, the inside of the trench 6 is insulated from the n⁻-type drift layer 2, the p⁻-type base layer 3, and the n⁺-type source layer 4. The first insulating film 7 can be made of silicon oxide formed by e.g. CVD (Chemical Vapor Deposition) or thermal oxidation. The second insulating film 8 having a higher dielectric constant than the first insulating film 7 can be made of a dielectric, film having a high dielectric constant such as silicon nitride (SiN), alumina (Al₂O₃), and hafnium oxide (HfO₂). Here, the first insulating film is not limited to the silicon oxide film described above. Naturally, the first insulating film can be made of a different insulating film such as SiN as long as its dielectric constant is set lower than that of the second insulating film.

Inside this trench 6, a gate electrode 9 is buried via the first insulating film 7 and the second insulating film 8. The gate electrode 9 opposes the n⁻-type drift layer 2, the p⁻-type base layer 3, and the n⁺-type source layer 4 via the second insulating film 8. The gate electrode is made of e.g. p-type or n-type polysilicon. Materials having high conductivity other than polysilicon can also be used. An interlayer insulating film 10 is formed so as to cover the top of the gate electrode 9. The interlayer insulating film can be made of e.g. silicon oxide like the first insulating film 7, or other insulating films such as SiN. A source electrode 12 as a second electrode is formed on the interlayer insulating film 10, the p⁻-type base layer 3, and the n⁺-type source layer 4. The source electrode 12 is insulated from the gate electrode 9 by the interlayer insulating film 10. The source electrode 12 is in contact with, and electrically connected to, the source layer 4. The source electrode 12 is electrically connected to the p⁻-type base layer 3 through the p⁺-type contact layer 5. By the p⁺-type contact layer 5, the contact resistance can be reduced. However, without forming this layer, the source electrode 12 may be electrically connected to the p⁻-type base layer 3 by direct junction.

The power semiconductor device 100 of this invention is operated as follows. The gate electrode 9 is applied with a positive voltage relative to the source electrode 12. Then, an n-channel layer is formed in a portion of the p⁻-type base layer 3 opposing the gate electrode 9 via the second insulating film, i.e., in a portion which forms the side surface of the trench 6. Here, the drain electrode is applied with a positive voltage relative to the source electrode 12. Then, electrons flow from the source electrode through the n⁺-type source layer 4, the n-channel layer, the n⁻-type drift layer 2, and the n⁺-type semiconductor substrate 1 to the drain electrode 11. Thus, in the opposite direction, the current flows from the drain electrode to the source electrode.

In the power semiconductor device 100 of this embodiment, the second gate insulating film formed on a portion of the p⁻-type base layer 3 where the n-channel is formed has a higher dielectric constant than the silicon oxide film used as an ordinary gate insulating film. Hence, when the gate electrode 9 is applied with a positive voltage, the density of electrons in the n-channel layer formed on the side surface of the trench 6 made of the p⁻-type base layer increases. Consequently, the resistance of the n-channel layer is reduced.

In the upper region of the trench, the side surface of the trench 6 is formed by the p⁻-type base layer 3. The lower region of the trench 6 is located below this upper region. In the lower region of the trench 6, the side surface of the trench 6 is formed by the n⁻-type drift layer 2 and covered with the first insulating film having a lower dielectric constant than the second insulating film. In the lower region of the trench, particularly at its bottom surface and the side surface therearound, between the gate electrode 9 and the drain electrode 11, the first insulating film 7 is series connected to the junction of the first insulating film 7 and the n⁻-type drift layer 2. Of these two, the breakdown voltage of the power semiconductor device 100 depends on the breakdown voltage of the junction of the first insulating film 7 and the n⁻-type drift layer 2. Of the voltage between the gate electrode and the drain electrode (hereinafter referred to as gate-drain voltage), by increasing the partial voltage applied to the first insulating film 7, the partial voltage applied to the junction of the n⁻-type drift layer 2 and the first insulating film 7 in the n⁻-type drift layer 2 can be reduced. Hence, the breakdown voltage of the power semiconductor device 100 can be increased.

Here, to reduce the resistance of the n-channel layer, an insulating film having a high dielectric constant can be used for the second insulating film 8. However, if the same insulating film having a high dielectric constant is also used for the first insulating film 7, the aforementioned partial voltage of the gate-drain voltage applied to the junction of the n⁻-type drift layer 2 and the first insulating film in the n⁻-type drift layer 2 increases. This decreases the breakdown voltage of the power semiconductor device 100.

In contrast, in this embodiment, the first insulating film is an insulating film having a lower dielectric constant than the second insulating film. Thus, even if the dielectric constant of the second insulating film is increased to reduce the resistance of the n-channel layer, the partial voltage of the gate-drain voltage applied to the junction of the n⁻-type drift layer 2 and the first insulating film 7 in the n⁻-type drift layer 2 can be maintained at a low level. Hence, the on-resistance can be reduced while maintaining high breakdown voltage of the power semiconductor device.

The thickness of the first insulating film 7 can be adjusted depending on its dielectric constant to adjust the magnitude of the partial voltage of the gate-drain voltage applied to the junction of the n⁻-type drift layer 2 and the first insulating film 7 in the n⁻-type drift layer 2. By setting the dielectric constant and thickness of the first insulating film so as to reduce this partial voltage, the impurity concentration of the n⁻-type drift layer can be increased while maintaining the breakdown voltage. This enables further reduction of on-resistance.

### Second Embodiment

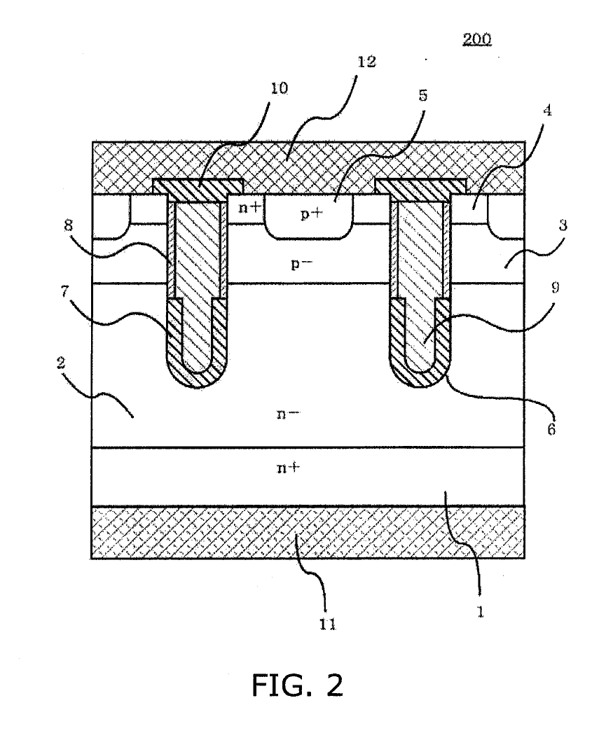

FIG. 2 is a diagram showing a cross section of a part of the principal part of a current-flowing device region of a power semiconductor device of a second embodiment of the invention. As shown in FIG. 2, the power semiconductor device 200 of the second embodiment of the invention is configured as follows. In the following description, the portions identical or similar to those of the above first embodiment are labeled with like reference numerals, and only the portions different from those of the first embodiment are described.

The power semiconductor device 200 of the second embodiment of the invention is different from the power semiconductor device 100 of the first embodiment in that the thickness of the first insulating film is set thicker than the thickness of the second insulating film in the lower region of the trench 6 where the gate electrode is buried via the first and second insulating film. The first insulating film 7 is made of an insulating film having a lower dielectric constant than the second insulating film 8 made of an insulating film having a high dielectric constant. Thus, like the first embodiment, the on-resistance can be reduced while maintaining high breakdown voltage. Furthermore, in this embodiment, the thickness of the first insulating film 7 is also thickened. Hence, the partial voltage of the gate-drain voltage applied to the first insulating film 7 further increases. This further reduces the partial voltage of the gate-drain voltage applied to the junction of the n⁻-type drift layer 2 and the first insulating film 7 in the n⁻-type drift layer 2, the junction being series connected to the first insulating film 7. Consequently, while maintaining the same breakdown voltage, the n-type impurity concentration of the n⁻-type drift layer can be further increased. Hence, the resistance of the n⁻-type drift layer can be reduced. Thus, the on-resistance can be made even lower than that of the power semiconductor device 100 of the first embodiment.

### Third Embodiment

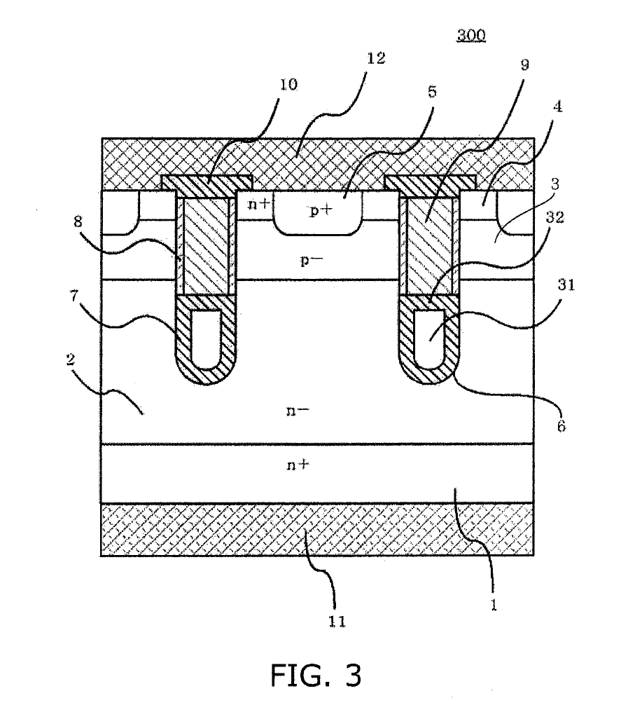

FIG. 3 is a diagram showing a cross section of a part of the principal part of a current-flowing device region of a power semiconductor device of a third embodiment of the invention. As shown in FIG. 3, the power semiconductor device 300 of the third embodiment of the invention is configured as follows. In the following description, the portions identical or similar to those of the above first embodiment are labeled with like reference numerals, and only the portions different from those of the first embodiment are described.

As described below, the power semiconductor device 300 of the third embodiment of the invention is different from the power semiconductor device 100 of the first embodiment in that a source buried electrode and a gate electrode are formed in the trench 6. The source buried electrode is buried in the trench 6 via the first insulating film. The gate electrode is insulated from the source buried electrode by a third insulating film formed above the source buried electrode, and is buried in the trench 6 via the second insulating film. In the lower region of the trench 6 where the bottom surface and side surface of the trench 6 are formed by the n⁻-type drift layer 2, a first insulating film 7 made of silicon oxide is formed so as to cover the bottom surface and side surface of the trench 6 similar to the first embodiment. Via this first insulating film, a source buried electrode 31 made of a conductive material electrically connected to the source electrode 12 is buried in the lower region of the trench 6. By way of example, the source buried electrode 31 can be made of p-type or n-type polysilicon. A third insulating film 32 is formed above the exposed portion of the source buried electrode 31 not enclosed by the first insulating film. The first insulating film and the third insulating film surround the source buried electrode, including a portion (not shown) for extracting the source buried electrode 31 to the outside of the trench 6. Except the portion for extracting the source buried electrode 31 to the outside of the trench 6, the principal part of the source buried electrode 31 is formed so that its upper surface on the source electrode 12 side is located on the drain electrode 11 side (lower side) of the junction interface between the n⁻-type drift layer 2 and the p⁻-type base layer 3. That is, the principal part of the source buried electrode 31 is entirely buried in the n⁻-type drift layer 2. In the aforementioned principal part of the source buried electrode 31, the first insulating film and the third insulating film are also formed so that the upper surface thereof is located on the drain electrode 11 side of the junction interface between the n⁻-type drift layer 2 and the p⁻-type base layer 3. By way of example, the third insulating film can be made of the same film as the first insulating film. That is, by way of example, the third insulating film can be a silicon oxide film. The source buried electrode 31 is insulated and spaced from the n⁻-type drift layer 2 via the first insulating film.

In the upper region above the lower region of the trench 6, a second insulating film 8 is formed so as to extend on the region from the side surface of the uppermost portion of the trench 6 formed by the n⁺-type source layer 4 across the side surface formed by the p⁻-type base layer 3 to the side surface formed by the n⁻-type drift layer 2. The second insulating film 8 has a second dielectric constant higher than the first dielectric constant. In this embodiment, by way of example, the thickness of the second insulating film 8 is set equal to the thickness of the first insulating film similar to the first embodiment. The second insulating film 8 is connected to the first insulating film 7 at a position near the p⁻-type base layer 3 on the side surface of the trench 6 formed by the n⁻-type drift layer 2. The first insulating film 7 and the second insulating film 8 cover entirely the bottom and side surface of the inside of the trench 6. That is, by the junction of the first insulating film 7 and the second insulating film 8 in the region near the p⁻-type base layer 3 on the side surface of the trench 6 formed by the n⁻-type drift layer 2, the inside of the trench 6 is insulated from the n⁻-type drift layer 2, the p⁻-type base layer 3, and the n⁺-type source layer 4.

Similar to the first embodiment, the second insulating film can be made of a dielectric film having a high dielectric constant such as silicon nitride (SiN), alumina (Al₂O₃), and hafnium oxide (HfO₂). Here, the first insulating film 7 and the third insulating film 32 are not limited to the silicon oxide film described above. Naturally, the first insulating film 7 and the third insulating film 32 can be made of a different insulating film such as SiN as long as their dielectric constant is set lower than that of the second insulating film 8.

Above the source buried electrode 31, a gate electrode 9 made of a conductive material such as p-type or n-type doped polysilicon is buried in the trench 6 via the third insulating film. The gate electrode 9 is insulated from the source buried electrode 31 by the third insulating film. The gate electrode 9 is buried in the trench 6 via the second insulating film 8. The gate electrode 9 opposes the n⁻-type drift layer 2, the p⁻-type base layer 3, and the n⁺-type source layer 4 via the second insulating film 8, and insulated from these layers by the second insulating film 8.

An interlayer insulating film 10 is formed on the upper surface of the gate electrode 9. The interlayer insulating film 10 is joined with the second insulating film at the top of the trench 6. A source electrode 12 is formed on the interlayer insulating film 10, the n⁺-type source layer 4, and the p⁺-type contact layer 5. The source electrode 12 is insulated from the gate electrode 9 by the interlayer insulating film 10. The source electrode 12 is electrically connected to the n⁺-type source layer 4. Furthermore, the source electrode 12 is electrically connected to the p⁺-type contact layer 5, and electrically connected to the p⁻-type base layer 3 through the p⁺-type contact layer 5. The p⁺-type contact layer 5 is formed in order to achieve good ohmic contact between the p⁻-type base layer 3 and the source electrode 12. However, the source electrode 12 may be directly electrically connected to the p⁻-type base layer 3.

Thus, the power semiconductor device 300 of this embodiment has the following structure. The source buried electrode 31 is formed via the first insulating film in the lower region of the trench 6 where the bottom surface and side surface of the trench are formed by the n⁻-type drift layer 2. The gate electrode 9 is buried above the source buried electrode 31 in the upper region of the trench 6 via the second insulating film 8. The gate electrode 9 is insulated from the source buried electrode 31 via the third insulating film 32. Similar to the first embodiment, the first insulating film is an insulating film having a lower dielectric constant than the second insulating film. Thus, even if the dielectric constant of the second insulating film is increased to reduce the resistance of the n-channel layer, the partial voltage of the source-drain voltage applied to the junction of the n⁻-type drift layer 2 and the first insulating film 7 in the lower region of the trench 6 can be maintained at a low level. Here, the partial voltage of the source-drain voltage, rather than the partial voltage of the gate-drain voltage, is applied to the junction of the n⁻-type drift layer 2 and the first insulating film 7 in the n⁻-type drift layer 2 in the lower region of the trench 6. This is because while the first insulating film 7 is placed between the gate electrode 9 and the drain electrode 11 in the first embodiment, the first insulating film 7 is placed between the source buried electrode 31 and the drain electrode 11 in this embodiment. Hence, in this embodiment as well, similar to the first embodiment, the on-resistance can be reduced while maintaining high breakdown voltage of the power semiconductor device.

Furthermore, in this embodiment, it is not the gate electrode 9 but the source buried electrode 31 that is buried in the lower region of the trench 6 via the first insulating film 7. This structure further achieves the following effect. That is, the gate-drain capacitance is reduced by the amount of the capacitance corresponding to the first insulating film which is, in the first embodiment, sandwiched between the gate electrode 9 and the n⁻-type drift layer 2. Thus, the switching loss can be reduced.

Similar to the first embodiment, the thickness of the first insulating film 7 can be adjusted depending on its dielectric constant to adjust the magnitude of the partial voltage of the source-drain voltage applied to the junction of the n⁻-type drift layer 2 and the first insulating film 7 in the n⁻-type drift layer 2. By setting the dielectric constant and thickness of the first insulating film 7 so as to reduce this partial voltage, the impurity concentration of the n⁻-type drift layer 2 can be increased while maintaining the breakdown voltage. This enables further reduction of on-resistance.

### Fourth Embodiment

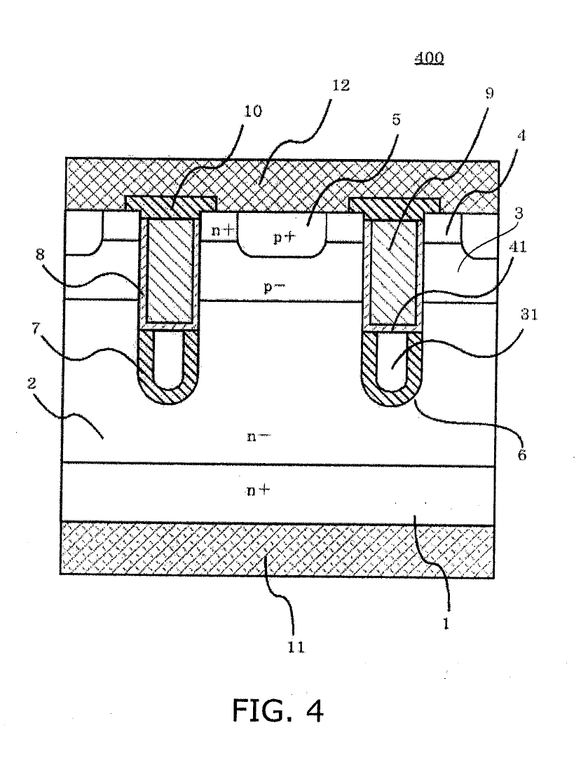

FIG. 4 is a diagram showing a cross section of a part of the principal part of a current-flowing device region of a power semiconductor device of a fourth embodiment of the invention. As shown in FIG. 4, the power semiconductor device 400 of the fourth embodiment of the invention is configured as follows. In the following description, the portions identical or similar to those of the above third embodiment are labeled with like reference numerals, and only the portions different from those of the third embodiment are described.

In the power semiconductor device 300 of the third embodiment, the source buried electrode 31 and the gate electrode 9 are buried, respectively, via the first insulating film and the second insulating film in the lower region and the upper region of the trench 6. The source buried electrode 31 and the gate electrode 9 are insulated from each other by the third insulating film. The third insulating film is made of the same material as the first insulating film, and joined with the first insulating film at a position near the p⁻-type base layer 3 on the side surface of the trench 6 formed by the n⁻-type drift layer 2. In contrast, the power semiconductor device 400 of the fourth embodiment of the invention is different in that the third insulating film 41 is joined with the second insulating film 8 at a position near the p⁻-type base layer 3 on the side surface of the trench 6 formed by the n⁻-type drift layer 2, and that the source buried electrode 31 and the gate electrode 9 are insulated from each other by this third insulating film 41. The third insulating film 41 is made of the same material as the second insulating film 8. Similar to the third embodiment, the third insulating film is formed so that its upper surface is located on the drain electrode 11 side of the junction interface between the n⁻-type drift layer 2 and the p⁻-type base layer 3.

The power semiconductor device 400 of this embodiment has the same structure as the power semiconductor device 300 except the difference in the material of the third insulating film 41. Hence, the power semiconductor device 400 achieves the same effect as the power semiconductor device 300 of the third embodiment. In the description of the third and fourth embodiments, by way of example, the third insulating film is made of the same material as either the first insulating film or the second insulating film. However, the structure of the third embodiment may be combined with that of the fourth embodiment. More specifically, the third insulating film may have a vertically stacked structure in which the film 32 made of the same material as the first insulating film 7 and joined with the first insulating film 7 is overlaid by the film 41 made of the same material as the second insulating film 8 and joined with the second insulating film 8. In this case as well, the third insulating film is formed so that its upper surface is located on the drain electrode 11 side of the junction interface between the n⁻-type drift layer 2 and the p⁻-type base layer, 3.

The embodiments have been described with reference to the above examples. However, the embodiments are not limited to the configuration illustrated in the examples. It is understood that the constituent material, layer thickness, and pattern configuration can be modified within the scope not departing from the spirit of the invention. Furthermore, the film formation method, film formation condition, etching method, and etching condition of the layers, or the method for planarizing the substrate surface, can be practiced within the scope not departing from the spirit of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

1. A power semiconductor device comprising:
a first semiconductor layer of a first conductivity type;
a second semiconductor layer of the first conductivity type formed on a first major surface of the first semiconductor layer and having a lower impurity concentration than the first semiconductor layer;
a third semiconductor layer of a second conductivity type selectively formed in a surface of the second semiconductor layer;
a fourth semiconductor layer of the first conductivity type selectively formed in a surface of the third semiconductor layer;
a first insulating film having a first dielectric constant and formed on a bottom surface and a side surface of a trench formed by the second semiconductor layer, the trench being in contact with the fourth semiconductor layer and extending from a surface of the fourth semiconductor layer through the third semiconductor layer to the second semiconductor layer;
a second insulating film formed on a side surface of the trench formed by the third semiconductor layer and a side surface of the trench formed by the fourth semiconductor layer, the second insulating film being connected to the first insulating film on the side surface of the trench formed by the second semiconductor layer, and the second insulating film having a second dielectric constant higher than the first dielectric constant;
a gate electrode buried in the trench via the first insulating film and the second insulating film;
an interlayer insulating film formed on the gate electrode;
a first main electrode electrically connected to a second major surface of the first semiconductor layer on a side opposite to the first major surface; and
a second main electrode formed on the surface of the fourth semiconductor layer and on the interlayer insulating film, electrically connected to the third semiconductor layer and the fourth semiconductor layer, and insulated from the gate electrode by the interlayer insulating film.

2. The device according to claim 1, wherein the gate electrode oppose the second semiconductor layer, the third semiconductor layer, and the fourth semiconductor layer via the second insulating film.

3. The device according to claim 1, wherein an end of the first insulating film on the second main electrode side is formed on the first main electrode side of a junction interface between the second semiconductor layer and the third semiconductor layer.

4. The device according to claim 1, wherein the first insulating film has a thicker film thickness than the second insulating film.

5. The device according to claim 1, further comprising:
a fifth semiconductor layer of the second conductivity type having a higher impurity concentration than the third semiconductor layer and formed between the second main electrode and the third semiconductor layer.

6. The device according to claim 1, wherein the second insulating film is made of one of SiN, Al₂O₃, and HfO₂.

7. A power semiconductor device comprising:
a first semiconductor layer of a first conductivity type;
a second semiconductor layer of the first conductivity type formed on a first major surface of the first semiconductor layer and having a lower impurity concentration than the first semiconductor layer;
a third semiconductor layer of a second conductivity type selectively formed in a surface of the second semiconductor layer;
a fourth semiconductor layer of the first conductivity type selectively formed in a surface of the third semiconductor layer;
a first insulating film having a first dielectric constant and formed on a bottom surface and a side surface of a trench formed by the second semiconductor layer, the trench being in contact with the fourth semiconductor layer and extending from a surface of the fourth semiconductor layer through the third semiconductor layer to the second semiconductor layer;
a second insulating film formed on a side surface of the trench formed by the third semiconductor layer and a side surface of the trench formed by the fourth semiconductor layer, the second insulating film being connected to the first insulating film on the side surface of the trench formed by the second semiconductor layer, and the second insulating film having a second dielectric constant higher than the first dielectric constant;
a buried electrode buried in the trench via the first insulating film;
a third insulating film formed above the buried electrode;
a gate electrode insulated from the buried electrode by the third insulating film and buried in the trench via the second insulating film;
an interlayer insulating film formed on the gate electrode;
a first main electrode electrically connected to a second major surface of the first semiconductor layer on a side opposite to the first major surface; and
a second main electrode formed on the surface of the fourth semiconductor layer and on the interlayer insulating film, electrically connected to the third semiconductor layer and the fourth semiconductor layer, and insulated from the gate electrode by the interlayer insulating film.

8. The device according to claim 7, wherein the buried electrode is electrically connected to the second main electrode.

9. The device according to claim 7, wherein the third insulating film is made of a same material as the first insulating film and joined with the first insulating film.

10. The device according to claim 7, wherein the third insulating film is made of a same material as the second insulating film and joined with the second insulating film.

11. The device according to claim 7, wherein the third insulating film includes:
a portion joined with the first insulating film and made of a same material as the first insulating film; and
one other portion joined with the second insulating film and made of a same material as the second insulating film.

12. The device according to claim 7, wherein the gate electrode oppose the second semiconductor layer, the third semiconductor layer, and the fourth semiconductor layer via the second insulating film.

13. The device according to claim 7, wherein an end of the first insulating film on the second main electrode side is formed on the first main electrode side of a junction interface between the second semiconductor layer and the third semiconductor layer.

14. The device according to claim 7, wherein the first insulating film has a thicker film thickness than the second insulating film.

15. The device according to claim 7, further comprising:
a fifth semiconductor layer of the second conductivity type having a higher impurity concentration than the third semiconductor layer and formed between the second main electrode and the third semiconductor layer.

16. The device according to claim 7, wherein an end of the buried electrode on the second main electrode side is formed on the first main electrode side of a junction interface between the second semiconductor layer and the third semiconductor layer.

17. The device according to claim 7, wherein an end of the third insulating film on the second main electrode side is formed on the first main electrode side of a junction interface between the second semiconductor layer and the third semiconductor layer.

18. The device according to claim 7, wherein the second insulating film is made of one of SiN, Al₂O₃, and HfO₂.
